(19) United States
(12) Patent Application Publication
(10) Pub. No.: US 2022/0048762 A1
(43) Pub. Date: Feb. 17, 2022

(54) VOID REDUCTION ON WAFER BONDING INTERFACE

(71) Applicant: BEIJING VOYAGER TECHNOLOGY CO., LTD., Beijing (CN)

(72) Inventors: Sergio Almeida, Mountain View, CA (US); Qin Zhou, Mountain View, CA (US); Youmin Wang, Mountain View, CA (US)

(73) Assignee: BEIJING VOYAGER TECHNOLOGY CO., LTD., Beijing (CN)

(21) Appl. No.: 16/994,474

(22) Filed: Aug. 14, 2020

(51) Int. Cl. B81C 1/00

(52) U.S. Cl. CPC B81C 1/00269; B81C 2203/0118; B81C 1/00849

(57) ABSTRACT

Embodiments of the disclosure provide methods of bonding silicon wafers. An exemplary method may include cleaning the silicon wafers to remove residues. The method may also include performing a hydrophilic treatment to surfaces of the silicon wafers to increase surface energy. The method may also include pre-bonding the silicon wafers at room temperature. In addition, the method may include performing a rapid thermal annealing treatment to the pre-bonded silicon wafers to bond the silicon wafers.

### TECHNICAL FIELD

The present disclosure relates to semiconductor fabrication processes, and more particularly to, bonding semiconductor wafers with reduced voids on the bonding interface.

### BACKGROUND

Wafer bonding is a packaging technology on wafer-level for the fabrication of microelectromechanical systems (MEMS), nanoelectromechanical systems (NEMS), microelectronics and optoelectronics, ensuring a mechanically stable and hermetically sealed encapsulation. The wafers' diameters may range from 100 mm to 200 mm (4 inches to 8 inches) for MEMS/NEMS and up to 300 mm (12 inches) to produce microelectronic devices.

In MEMS and NEMS, the package protects the sensitive internal structures from environmental influences such as temperature, moisture, high pressure, and oxidizing species. The long-term stability and reliability of the functional elements depend on the encapsulation process.

Conventional wafer bonding processes face a problem of forming voids or bubbles on the bonding interface, partly attributing to hydrogen diffusion along the bonding interface nucleating around hydrocarbons left on the wafer surface. Hydrogen and hydrocarbon free surfaces are typically achieved by a pre-heating treatment followed by a pre-bonding process in an ultra-high vacuum (e.g., 10⁻⁹ torr) environment, which is expensive and sometimes unpractical.

Embodiments of the disclosure prevent the formation of voids on the bonding interface by cleaning the wafers using an improved cleaning solution followed by a rapid thermal annealing process.

### SUMMARY

In one example, embodiments of the disclosure provide a method of bonding silicon wafers. The method may include cleaning the silicon wafers to remove residues. The method may also include performing a hydrophilic treatment to surfaces of the silicon wafers to increase surface energy. The method may further include pre-bonding the silicon wafers at room temperature. In addition, the method may include performing a rapid thermal annealing treatment to the pre-bonded silicon wafers to bond the silicon wafers.

In another example, embodiments of the disclosure provide a method of bonding silicon wafers. The method may include cleaning the silicon wafers using a cleaning solution comprising ammonium hydroxide (NH₄OH) and deionized water. A ratio of composition between the NH₄OH and the deionized water may be between 1:20 and 1:35. The method may also include pre-bonding the silicon wafers at room temperature. The method may further include performing a rapid thermal annealing treatment to the pre-bonded silicon wafers to bond the silicon wafers.

In another example, embodiments of the disclosure provide a method of bonding silicon wafers. The method may include pre-bonding the silicon wafers at room temperature. The method may also include heating the pre-bonded silicon wafers to a temperature higher than a predetermined threshold to bond the silicon wafers. The method may further include rapidly cooling down the bonded silicon wafers. A rate of cooling down may be substantially equal to a rate of heating the pre-bonded silicon wafers.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a schematic diagram of an exemplary method 100 for bonding semiconductor wafers, according to embodiments of the disclosure.

FIG. 2 illustrates several exemplary temperature profiles and their impacts on void formation, according to embodiments of the disclosure.

FIG. 3 illustrates a flow chart of an exemplary method for bonding semiconductor wafers, according to embodiments of the disclosure.

FIG. 4 illustrates a flow chart of an exemplary implementation of a step of the method shown in FIG. 3, according to embodiments of the disclosure.

FIG. 5 shows an inferred (IR) picture of a Si-Si wafer bonded with a conventional process.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

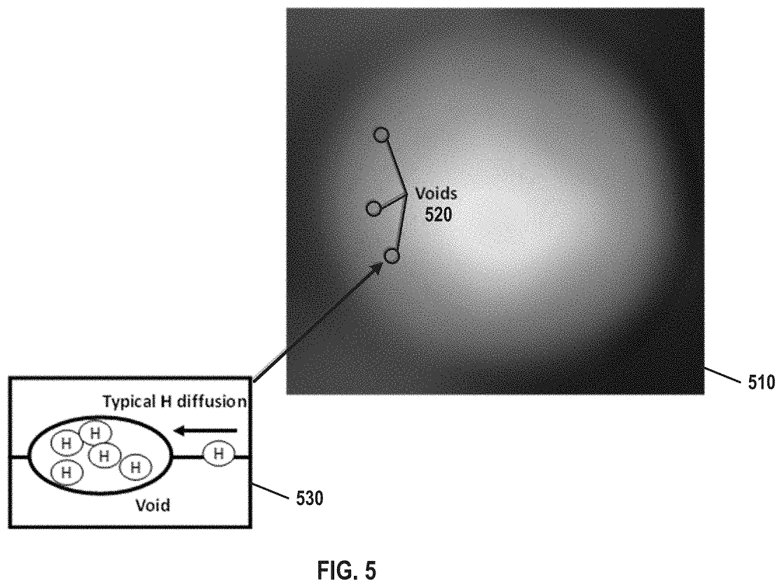

Embodiments of the present disclosure provide methods for bonding semiconductor wafers such as silicon (Si) wafers. Wafer bonding is an important packaging technology in the fabrication of MEMS/NEMS or other semiconductor systems. In its simplest form, wafer bonding involves contacting two wafers at their opposing surfaces. The two wafer surfaces attract each other by van de Waals and/or ionic forces at room temperature. A strong bonding (e.g., a covalent bond) can be subsequently formed at elevated temperatures. One important measure for evaluating the quality of the bonding is whether or how many voids (e.g., bubbles caused by gas accumulation) are present at the bonding interface (e.g., where the two wafer surfaces meet or a vicinity thereof). A void-free bonding interface is desirable or sometimes required to fulfill packaging requirements such as protection against environmental influences, heat dissipation, and maintenance of energy and information flow. Conventional bonding methods, however, lack a reliable and economical way to form strong bonding and to prevent the formation of voids. For example, to clean the wafers before bonding, RCA clean, a cleaning solution, is typically used. But conventional RCA clean contains too much Si-etching chemical that would cause micro-roughness on the surface of the wafers, compromising the bonding strength. In addition, void formation is often attributed to hydrogen diffusion along the bonding interface nucleating around hydrocarbons. FIG. 5 shows an inferred (IR) picture 510 of a Si-Si wafer bonded with a conventional process. As shown in FIG. 5, voids 520 are present at the bonding interface. Formation of voids 520 is caused by hydrogen diffusion during high temperature annealing, when hydrogen atoms diffuse onto the bounding interface and form the voids, as shown in diagram 530. Conventional methods to suppress the formation of voids require a pre-heating process followed by a pre-bonding process in an ultra-high vacuum (e.g., 10⁻⁹ torr) environment, which is expensive and sometimes even unpractical.

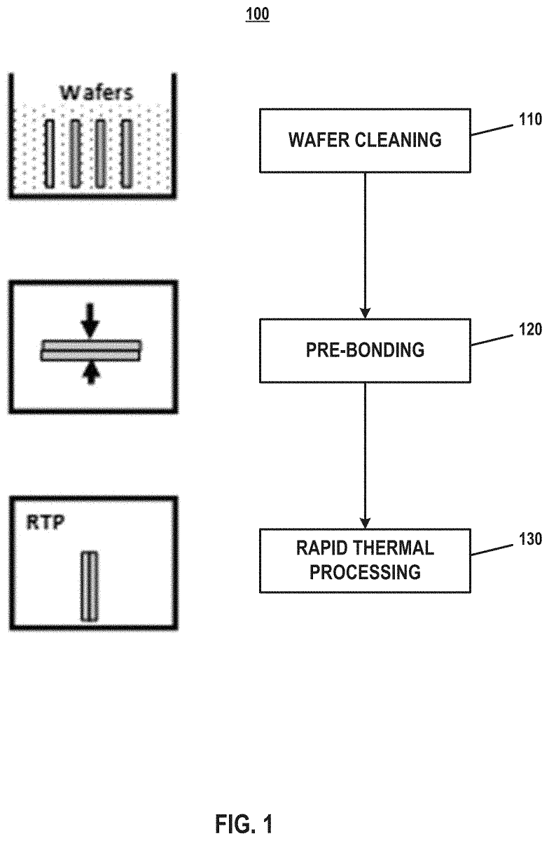

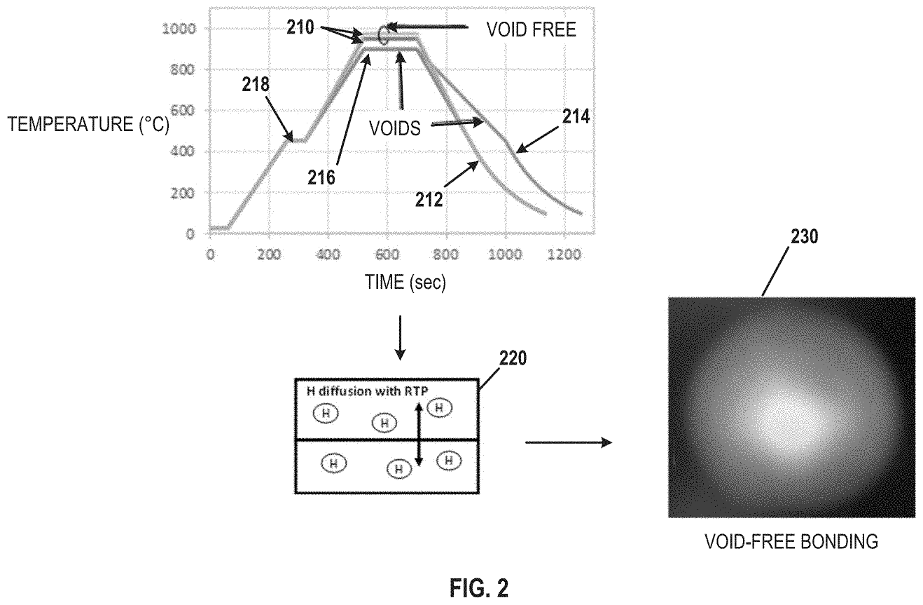

FIG. 1 illustrates a schematic diagram of an exemplary method 100 for bonding semiconductor wafers, according to embodiments of the disclosure. As shown in FIG. 1, method 100 generally includes three main steps, the detail of which will be described in connection with FIGS. 2-4.

In main step 110, the wafers to be bonded undergo a cleaning process, in which the wafers are submerged into one or more kinds of cleaning solutions to remove organic residues from their surfaces. For example, the wafers may undergo a solvent clean process, in which the wafers are placed in acetone bath and then methanol bath, followed by a deionized (DI) water rinse.

In another example, the wafers may undergo an RCA cleaning process, in which the wafers are submerged into a cleaning solution consisting of ammonium hydroxide (NH₄OH), hydrogen peroxide (H₂O₂), and deionized water (H₂O) mixed together according to a specific recipe. RCA cleaning can create native oxide and hydrophilic wafer surfaces. It can also help to prevent particle attachment to the wafer surfaces during wafer transportation. However, NH₄OH etches Si, which may cause surface micro-roughness that would compromise the bonding strength. Reducing NH₄OH in the RCA cleaning solution can prevent the formation of micro-roughness but can also increase the risk of particle contamination. Embodiments of the present disclosure utilizes a composition mix of the cleaning solution that both prevents the formation of micro-roughness and particle contamination.

In a further example, the wafers may undergo a hydrofluoric acid (HF) dip process, in which the wafers are dipped into a HF bath for a short period of time. Because the HD dip process removes hydrophilic oxide, the wafers may turn more hydrophobic, and may require other follow-up processes to make the surfaces more hydrophilic.

In yet another example, the wafers may undergo a piranha etch process, in which the wafers are submerged into a piranha solution, a mixture of sulfuric acid (H₂SO₄), water, and H₂O₂. The piranha process also hydroxylates the wafer surfaces, making them hydrophilic.

In main step 120, the cleaned wafers may undergo a pre-bonding process, in which Si surfaces contact each other at room temperature. The contacted surfaces attract each other by van de Waals and/or ionic forces, forming an initial weak bond.

In main step 130, a rapid thermal processing (RTP) may be carried out to form a strong bond (e.g., creating covalent bonds) between the pre-bonded wafer surfaces. One objective of the RTP is to heat and cool the wafers according to a specific temperature profile that changes the direction of hydrogen diffusion. Instead of diffusing onto the bonding interface to cause formation of voids, hydrogen atoms diffuse into the pre-bonded wafers under certain temperature profiles, thereby preventing the formation of voids.

FIG. 2 illustrates several exemplary temperature profiles and their impacts on void formation, according to embodiments of the disclosure. Referring to FIG. 2, voids are formed when the top temperature is not high enough. For example, when the top temperature is lower than about 950° C., as indicated by temperature profile 216, voids are formed, regardless of whether the cooling process is rapid (as indicated by 212) or slow (as indicated by 214). On the other hand, when the top temperature is from about 950 to 975° C. (as indicated by temperature profiles 210), void free bonding can be achieved. Temperature profiles 210 cause a different direction of hydrogen diffusion than profile 216. As shown in diagram 220, during the RTP process in which temperature profiles 210 are applied, hydrogen atoms diffuse into silicon wafers, steering clear from the bonding interface. Therefore, no hydrogen accumulation occurs at the bonding interface, leading to void free bonding, as shown in IR image 230.

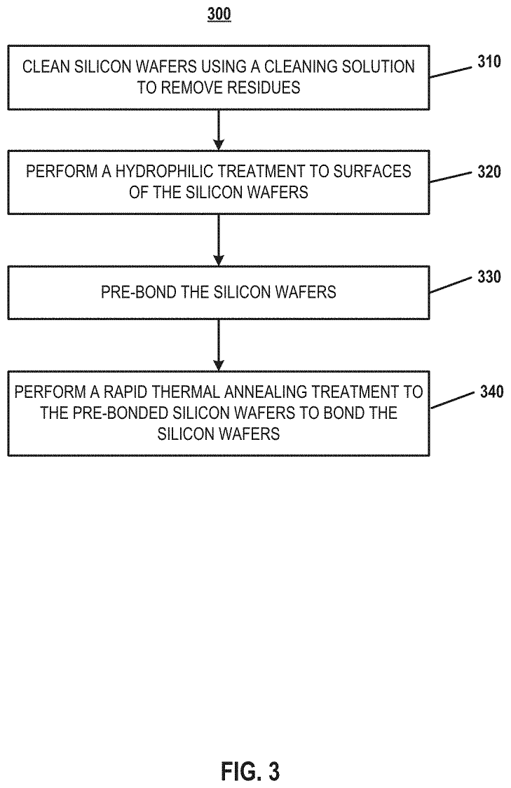

FIG. 3 illustrates a flow chart of an exemplary method 300 for bonding semiconductor wafers, according to embodiments of the disclosure. Method 300 is a more detailed implementation of the general method 100 described above. As shown in FIG. 3, method 300 may include multiple steps. It is to be appreciated that some of the steps may be omitted to perform method 300. Further, some of the steps may be performed simultaneously, or in a different order than shown in FIG. 3.

In step 310, silicon wafers may be cleaned using a cleaning solution to remove residues. As described above in connection with FIG. 1, various solutions can be used. In some embodiments, an improved RCA cleaning solution may be used. The improved RCA cleaning solution may contain a mixture of NH₄OH, H₂O₂, and deionized water. Balancing the effects of micro-roughness formation and particle contamination prevention, an optimal composition of the NH₄OH, H₂O₂, and deionized water may be used. For example, in some embodiments, a mixer of about 0.25 part of NH₄OH, about 1 part of H₂O₂, and about 6.5 parts of deionized water may be used. In some embodiments, the ratio of composition between NH₄OH and H₂O₂ can range from 0.2:1 to 0.3:1. In some embodiments, the ratio of composition between deionized water and H₂O₂ can range from 6:1 to 7:1. In some embodiments, the ratio of composition between NH₄OH and deionized water can range from 1:20 to 1:35. In some embodiments, the ratio of composition between NH₄OH and H₂O₂ can range from 1:5 to 1:3. It is noted that any value between the higher limit and the lower limit of a range can be used to make the improved RCA cleaning solution.

One advantage of the improved RCA cleaning solution is that the amount of NH₄OH is reduced compared to typical RCA cleans. This reduction in NH₄OH can reduce the formation of micro-roughness, while maintaining the ability to prevent particle contamination. In some embodiments, one or more other cleaning processes, such as solvent cleaning, HF dip cleaning, piranha cleaning, etc., may be used in combination with the improved RCA cleaning.

In step 320, a hydrophilic treatment may be performed to surfaces of the silicon wafers to increase surface energy. In some embodiments, after the cleaning process(es) in step 310, the wafer surfaces may not be sufficiently hydrophilic (water-compatible). It is desirable to have highly hydrophilic wafer surfaces before the bonding processes because a hydrophilic surface has high surface energy and therefore is adhesive to the counterpart surface. One exemplary hydrophilic treatment is to apply oxygen plasma to the silicon wafers to oxidize the surfaces of the silicon wafers. Because silicon oxide is hydrophilic, the oxygen plasma can improve the hydrophilic property of the silicon wafer surfaces. It is noted that some cleaning processes, such as RCA cleaning and piranha cleaning, can natively create oxide layers on the surfaces of the silicon wafers. Therefore, step 320 may be omitted in some embodiments.

In step 330, the cleaned silicon wafers may undergo a pre-bonding process, in which Si surfaces contact each other at room temperature, as described above in main step 120. The contacted surfaces attract each other by van de Waals and/or ionic forces, forming an initial weak bond.

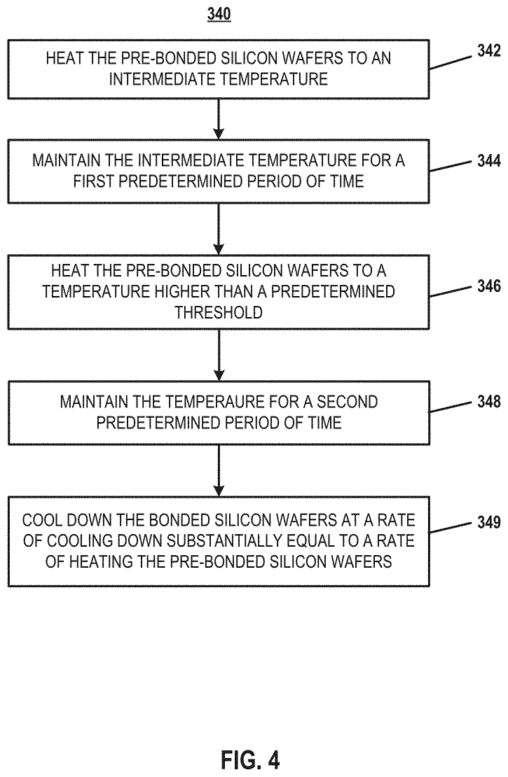

In step 340, a rapid thermal annealing treatment may be performed to the pre-bonded silicon wafers to bond the silicon wafers. As described above, the rapid thermal annealing treatment may include heating and cooling the pre-bonded silicon wafers according to a specific temperature profile that changes the direction of hydrogen diffusion to prevent the formation of voids on the bonding interface. FIG. 4 illustrates a flow chart of an exemplary implementation of step 340, according to embodiments of the disclosure. As shown in FIG. 4, step 340 may include multiple sub-steps. It is to be appreciated that some of the sub-steps may be omitted. Further, some of the sub-steps may be performed simultaneously, or in a different order than shown in FIG. 4.

In sub-step 342, the pre-bonded silicon wafers may be heated to an intermediate temperature. As shown in FIG. 2, an exemplary intermediate temperature is indicated by 218. The heating rate can be indicated by the slope of the temperature profile from the beginning of the heating to the intermediate temperature 218. In some embodiments, a rapid rising of temperature to the intermediate temperature 218 may help to achieve the desirable hydrogen diffusion direction.

Returning to FIG. 4, after heating the pre-bonded silicon wafers to the intermediate temperature, step 340 proceeds to sub-step 344, in which the intermediate temperature may be maintained for a first predetermined period of time. Turning again to FIG. 2, an exemplary first predetermined period of time is shown in the temperature profile curves where intermediate temperature 218 is held steady.

Returning to FIG. 4, step 340 proceeds from sub-step 344 to sub-step 346, in which the pre-bonded silicon wafers may be further heated to a temperature higher than a predetermined threshold. Turning again to FIG. 2, a second segment of temperature rising is shown in every temperature profile curve from the intermediate temperature 218 to the top temperature. Among the curves, profiles 210 reach the top temperatures in the range from about 950 to 975° C., while profile 216's top temperature is below 950° C. In some embodiments, the predetermined threshold may be set to be about 950° C. As a result, profiles 210 meet the requirement of sub-step 346, while profile 216 does not.

Returning to FIG. 4, step 340 proceeds from sub-step 346 to sub-step 348, in which the temperature may be maintained for a second predetermined period of time that is longer than the first predetermined period of time. Turning again to FIG. 2, an exemplary second predetermined period of time is shown in temperature profile curves 210 where the top temperatures are held steady. As shown in FIG. 2, the second predetermined period of time is longer than the first predetermined period of time.

Returning to FIG. 4, step 340 proceeds from sub-step 348 to sub-step 349, in which the silicon wafers may be cooled down at a rate of cooling down substantially equal to a rate of heating the pre-bonded silicon wafers. Turning again to FIG. 2, the rate of cooling down can be indicated by the slopes of the temperature profiles. As shown in FIG. 2, the rate of temperature decreases for curves 212 is substantially equal to the rate of temperature increases for curves 210. This may help to achieve the desirable hydrogen diffusion direction. On the other hand, the rate of cooling down for curve 214 is not substantially equal to the corresponding rate of temperature increases, thereby not satisfying the requirement of sub-step 349.

The exemplary sub-steps shown in FIG. 4 and the exemplary temperature profile curves 210 shown in FIG. 2 are designed to perform a rapid thermal annealing treatment to bond silicon wafers. Rapid thermal annealing treatments performed according to such temperature profiles can cause hydrogen to diffuse into silicon wafers during the treatments, thereby preventing formation of voids on the bonding interface. In other words, the disclosed rapid thermal annealing treatments can prevent hydrogen from diffusing into the bonding interface between silicon wafers, improving the bonding quality.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

1. A method of bonding silicon wafers, the method comprising:
cleaning the silicon wafers to remove residues;
performing a hydrophilic treatment to surfaces of the silicon wafers to increase surface energy;
pre-bonding the silicon wafers at room temperature; and
performing a rapid thermal annealing treatment to the pre-bonded silicon wafers to bond the silicon wafers.

2. The method of claim 1, wherein cleaning the silicon wafers comprises:
cleaning the silicon wafers using a cleaning solution comprising: about 0.2-0.3 part of ammonium hydroxide (NH₄OH), about 1 part of hydrogen peroxide (H₂O₂), and about 6-7 parts of deionized water.

3. The method of claim 1, wherein performing the hydrophilic treatment comprises:
applying oxygen plasma to the silicon wafers to oxidize surfaces of the silicon wafers.

4. The method of claim 1, wherein performing the rapid thermal annealing treatment comprises:
heating the pre-bonded silicon wafers to a temperature higher than a predetermined threshold to bond the silicon wafers.

5. The method of claim 4, wherein the predetermined threshold is about 950° C.

6. The method of claim 4, wherein performing the rapid thermal annealing treatment comprises:
before heating the pre-bonded silicon wafers to the temperature higher than the predetermined threshold, heating the pre-bonded silicon wafers to an intermediate temperature lower than the predetermined threshold and maintaining the intermediate temperature for a first predetermined time period.

7. The method of claim 6, wherein performing the rapid thermal annealing treatment comprises:
after heating the pre-bonded silicon wafers to the temperature higher than the predetermined threshold, maintaining the temperature for a second predetermined time period that is longer than the first predetermined time period.

8. The method of claim 4, wherein performing the rapid thermal annealing treatment comprises:
cooling down the bonded silicon wafers, wherein a rate of cooling down is substantially equal to a rate of heating the pre-bonded silicon wafers.

9. The method of claim 1, wherein performing the rapid thermal annealing treatment comprises:
performing the rapid thermal annealing treatment according to a temperature profile that causes hydrogen to diffuse into the pre-bonded silicon wafers.

10. The method of claim 1, wherein performing the rapid thermal annealing treatment comprises:
performing the rapid thermal annealing treatment according to a temperature profile that prevent hydrogen from diffusing into an interface between the pre-bonded silicon wafers.

11. A method of bonding silicon wafers, the method comprising:
cleaning the silicon wafers using a cleaning solution comprising ammonium hydroxide (NH₄OH) and deionized water, wherein a ratio of composition between the NH₄OH and the deionized water is between 1:20 and 1:35;
pre-bonding the silicon wafers at room temperature; and
performing a rapid thermal annealing treatment to the pre-bonded silicon wafers to bond the silicon wafers.

12. The method of claim 11, wherein the clean solution further comprises hydrogen peroxide (H₂O₂), and a ratio of composition between the NH₄OH and the H₂O₂ is between 1:5 and 1:3.

13. The method of claim 11, wherein performing the rapid thermal annealing treatment comprises:
heating the pre-bonded silicon wafers to a temperature higher than a predetermined threshold to bond the silicon wafers.

14. The method of claim 13, wherein the predetermined threshold is about 950° C.

15. The method of claim 13, wherein performing the rapid thermal annealing treatment comprises:
before heating the pre-bonded silicon wafers to the temperature higher than the predetermined threshold, heating the pre-bonded silicon wafers to an intermediate temperature lower than the predetermined threshold and maintaining the intermediate temperature for a first predetermined time period.

16. The method of claim 15, wherein performing the rapid thermal annealing treatment comprises:
after heating the pre-bonded silicon wafers to the temperature higher than the predetermined threshold, maintaining the temperature for a second predetermined time period that is longer than the first predetermined time period.

17. The method of claim 13, wherein performing the rapid thermal annealing treatment comprises:
rapidly cooling down the bonded silicon wafers, wherein a rate of cooling down is substantially equal to a rate of heating the pre-bonded silicon wafers.

18. The method of claim 11, wherein performing the rapid thermal annealing treatment comprises:
performing the rapid thermal annealing treatment according to a temperature profile that causes hydrogen to diffuse into the pre-bonded silicon wafers.

19. The method of claim 11, wherein performing the rapid thermal annealing treatment comprises:
performing the rapid thermal annealing treatment according to a temperature profile that prevent hydrogen from diffusing into an interface between the pre-bonded silicon wafers.

20. A method of bonding silicon wafers, the method comprising:
pre-bonding the silicon wafers at room temperature;
heating the pre-bonded silicon wafers to a temperature higher than a predetermined threshold to bond the silicon wafers; and
rapidly cooling down the bonded silicon wafers, wherein a rate of cooling down is substantially equal to a rate of heating the pre-bonded silicon wafers.
